(19) United States
(12) Patent Application Publication
(10) Pub. No.: US 2009/0196377 A1
(43) Pub. Date: Aug. 6, 2009

(54) CORRELATION SYSTEM AND METHOD FOR GNSS RECEIVER

(75) Inventors: Jui-ming Wei, Taichung City (TW); Ming-hung Li, Wurih Township (TW); Jhih-siang Jhang, Taipei City (TW)

Correspondence Address: KIRTON AND MCCONKIE, 60 EAST SOUTH TEMPLE,, SUITE 1800, SALT LAKE CITY, UT, 84111, US

(73) Assignee: MEDIATEK INC., Hsin-Chu (TW)

(21) Appl. No.: 12/023,282

(22) Filed: Jan. 31, 2008

(51) Int. Cl. H03D 1/00; H04L 27/06

(52) U.S. Cl. 375/340

(57) ABSTRACT

A correlation system for a GNSS receiver uses an FFT engine to perform correlation and post-FFT operation. The FFT engine executes FFT operation to an input data stream so as to generate a frequency-domain correlation with frequency-domain C/A code and IFFT operation to the frequency-domain correlation result to generate post correlation data for each hypothesis, and executes FFT operation to the post correlation data of a selected hypothesis to generate a post-correlation FFT result in a programmable TDM manner. In the present invention, in addition to the FFT engine, some components such as a magnitude calculation unit and memory are shared by a correlation stage and a post-correlation stage. Therefore, hardware complexity can be reduced.

### TECHNICAL FIELD OF THE INVENTION

The present invention relates to a GNSS (Global Navigation Satellite System) receiver, more particularly, to a correlation system and method for a GNSS receiver using FFT (Fast Fourier Transform) techniques.

### BACKGROUND OF THE INVENTION

Fast Fourier Transform (FFT), which is well known in digital signal processing, has been applied in satellite communication, such as GNSS (Global Navigation Satellite System). For a GNSS receiver, TTFF (Time to First Fix), which generally means that at least four satellite are found for 3D positioning, is always a key issue for a user. To improve the performance of TTFF, a long period of integration for acquiring a satellite signal is undesirable. FFT solution provides powerful ability to improve correlation speed and signal acquisition and tracking performances.

To acquire a satellite, at least three domains must be considered. The three domains include visible satellites, code phases and Doppler frequency bins. A set of a specific satellite, a specific code phase and a specific Doppler frequency bin is called a hypothesis. The receiver detects the signal, which is spread-spectrum coded, from a specific satellite by correlating the signal with delayed versions of a spreading code (e.g. PRN (Pseudo Random Noise) code). If the correlation result is sufficiently high, it means that the receiver hits the satellite. This is called “acquisition”. After that, the receiver uses the delayed spreading code to achieve synchronization with the signal transmission from the satellite. This is called “tracking”. For a specific satellite and a specific Doppler frequency bin, a GPS receiver needs to search 1023 code phases, for example. Conventionally, correlations for the 1023 code phases are done in a TDM (Time Division Multiplexing) manner. As can be known, it will take a long time. In addition, due to noises and other interference, the accuracy and sensitivity of the receiver are influenced. It will be desirable if an additional process is provided after correlation to promote the receiver performances. FFT is a suitable solution to satisfy these requirements. FFT solution provides powerful correlating capability which is helpful in quick signal acquisition, but the huge memory requirement for post processing is a real burden in hardware cost.

### SUMMARY OF THE INVENTION

The present invention is to provide a correlation system for a GNSS receiver. The correlation system uses an FFT engine to perform correlation and post-FFT to promote receiver performance. In the receiver of the present invention, the FFT engine is used to execute FFT operation to an input data stream so as to generate a frequency-domain correlation with frequency-domain C/A code and IFFT operation to the frequency-domain correlation result to generate post correlation data for each hypothesis at a correlation stage, and executes FFT operation to the post correlation data of a selected hypothesis to generate a post-correlation FFT result at a post-correlation stage. The FFT engine executes these operations in a programmable TDM manner. An FFT buffer for storing the data stream, IFFT buffer for storing the frequency-domain correlation result and hypothesis buffer for storing the post-correlation FFT result for the selected hypothesis can be implemented by a single data buffer divided into three portions. The system has a magnitude calculation unit for calculating magnitude of the correlation result or the FFT result. That is, the magnitude calculation unit is shared for both the correlation stage and post-correlation stage. The system further has a spectrum memory for storing the post-correlation FFT result. In addition, the spectrum memory also accumulates coherent integration result of the correlation result for incoherent integration of the signal.

The present invention further provides another correlation system. The correlation system uses a time-domain correlator to execute correlation operation to a signal data stream. In addition, the system uses an FFT engine to perform post-correlation FFT to the correlation result to obtain a post-correlation FFT result so as to promote the receiver performance. The system has a magnitude calculation unit for calculating magnitude of the correlation result or the FFT result of the post-correlation FFT. The system further has a spectrum memory for storing the post-correlation FFT result. In addition, the memory also accumulates coherent integration result of the correlation result for incoherent integration of the signal.

By sharing some essential components, the hardware complexity can be reduced while maintaining excellent receiver performance.

The present invention also provide a correlation method for a GNSS receiver. The method includes executing correlation operation to a data stream to generate post correlation data; accumulating the post correlation data to obtain a coherent integration result; selecting the post correlation data or the coherent integration result thereof; and conducting FFT operation to the selected post correlation or the coherent integration result to generate a post correlation FFT result. The correlation operation can be done in time domain or frequency domain.

### BRIEF DESCRIPTION OF THE DRAWINGS

FIG. 1 is a block diagram schematically and generally showing a GNSS receiver in accordance with a first embodiment of the present invention;

FIG. 2 is a flow chart generally showing main steps of a correlation method in accordance with the present invention;

FIG. 3 schematically and roughly shows a two dimensional hypotheses distribution constructed by code phase and frequency; and

FIG. 4 is a block diagram schematically and generally showing a rear portion of a GNSS receiver in accordance with a second embodiment of the present invention.

### DETAILED DESCRIPTION OF THE INVENTION

The present invention will be described in detail in conjunction with the appending drawings.

If sampling frequency for input data is 1.023 MHz, then 1023 data points are obtained every millisecond (ms). For a specific satellite and specific Doppler frequency bin, the signal data stream is transformed into frequency domain (FFT), correlations (multiplying and adding operations) for 1023 code phases are done at the same time, then the correlation results are converted back to time domain, which is known as IFFT (Inverse FFT). The effects of FFT correlation, which is referred to as pre-correlation FFT and time domain correlation are equivalent. The time period for correlation is much shorter for pre-correlation FFT with the price of more power consumption in comparison with time-domain correlation. However, since rapid acquisition is essential for a GNSS receiver, pre-correlation FFT can be a desirable choice.

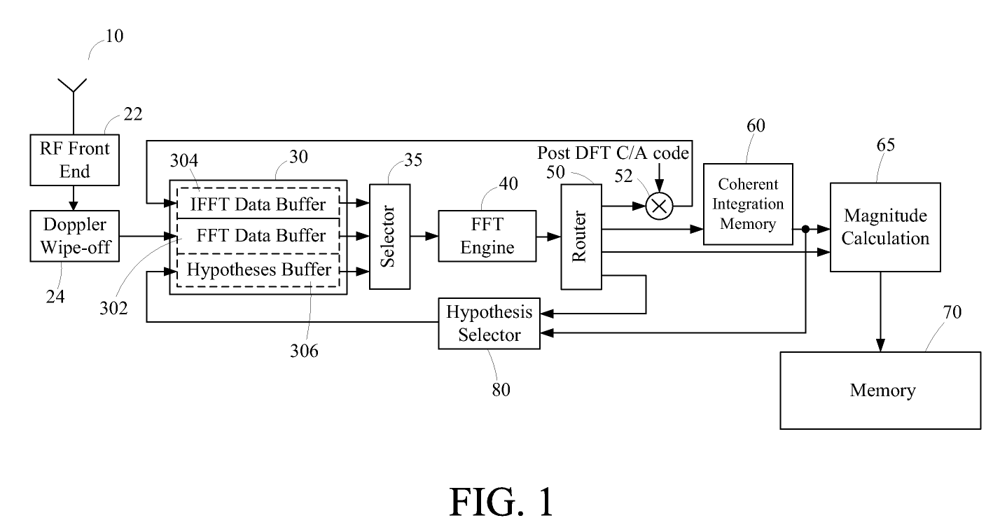

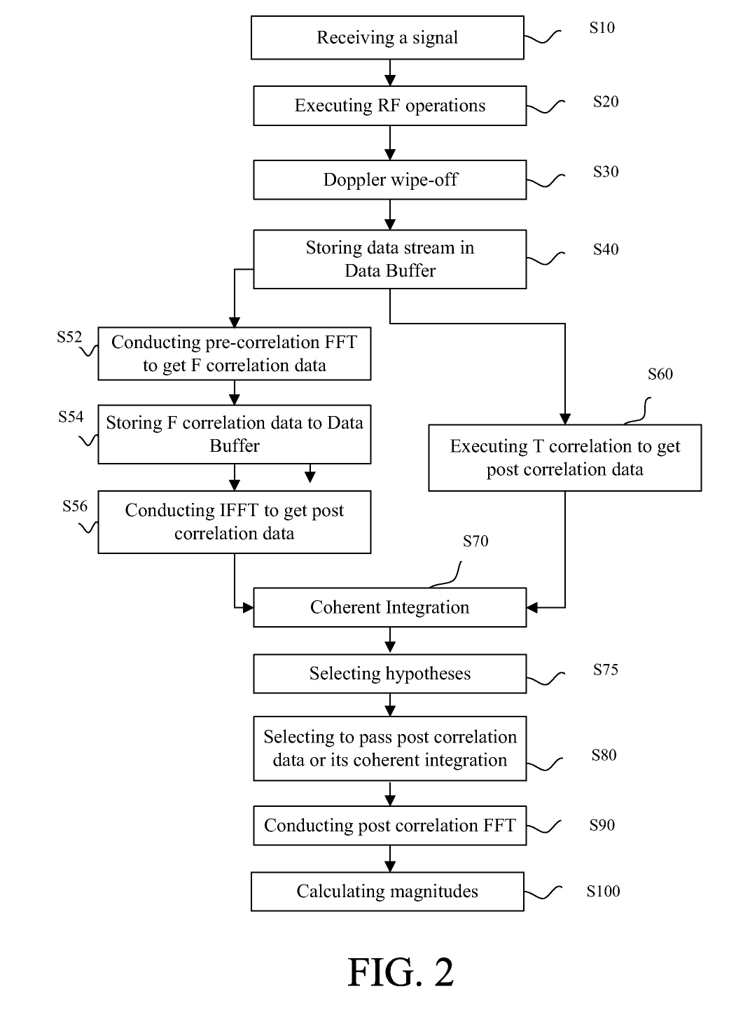

FIG. 1 is a block diagram schematically and generally showing a GNSS receiver having a correlation system in accordance with a first embodiment of the present invention. FIG. 2 is a flow chart generally showing a correlation method executed on the receiver. The receiver has an antenna 10 for receiving a signal for each hypothesis (step S10), a RF (radio frequency) front end 22 for executing RF related operations (step S20) mainly including down-conversion and digitization to a data stream of the signal. The receiver further has a Doppler wipe-off unit 24 for removing Doppler frequency component from the data stream (step S30). The resultant data stream is stored in a data buffer 30 (step S40). As can be seen from the drawing, the data buffer 30 is divided into three portions: FFT data buffer region 302, IFFT data buffer region 304 and hypothesis buffer region 306, in the present embodiment. Since the scale of FFT increases by power of two, for 1023 data points per ms, 1024-point memory capacity is required for the FFT buffer region 302. The data stream output from the Doppler wipe-off unit 24 is stored into the FFT data buffer region 302. A selector 35 is used for selecting to pick up data from which region of the data buffer 30. At this stage, the selector 35 selects the data stream stored in the FFT data buffer region 302 to transfer. The data steam picked up from the FFT data buffer region 302 is provided to a FFT engine 40. The FFT engine 40 is implemented by an FFT kernel, which can be divided into several sub-FFT units operating in parallel to increase throughput. The sub-FFT units are programmable to support different lengths of FFT operations. In addition to FFT operation, the FFT kernel can also perform IFFT operation by adjusting mainly a twiddle factor. The FFT engine 40 triggers FFT operation for the data stream from the FFT data buffer region 302. This is referred to as “pre-correlation FFT” (step S52). The FFT result is multiplied with PRN code replica, which is processed with DFT (Discrete Fourier Transform) operation and also has 1024 points, by a mixer 52 to obtain frequency-domain correlation data. The frequency-domain correlation data is then stored back to the data buffer 30 via a router 50 (step S54). The frequency-domain correlation data is stored in the IFFT data buffer region 304 for successive processing. To convert the data stream into time domain, the selector 35 selects to output the data stored in the IFFT data buffer region 304 and passes it to the FFT engine 40. At this stage, the IFFT operation is triggered with the twiddle factor and coefficients in butterfly units of FFT being adjusted (step S56). The conversion between FFT and IFFT is well known, and therefore the descriptions thereof are omitted herein. The data processed with IFFT is the time-domain correlation data, which is referred to as “post correlation data” hereafter for the sake of description convenience.

The resultant IFFT data (i.e. the post correlation data) is stored in a coherent integration memory 60 via the router 50 (step S70). A magnitude calculation unit 65 is used for incoherent integration of the coherent integration results. After hypotheses of one millisecond have been completely collected, a post-correlation FFT is triggered.

If the hypothesis, of which the post correlation data is calculated and stored into the coherent integration memory 60, is selected (step S75), the post correlation data thereof is also sent to the hypothesis buffer region 306 of the data buffer 30 via the router 50 and a hypothesis selector 80, which will be further described later. Preferably, the hypotheses around the correlation peak are considered to be collected. The code phase range and point number for post-correlation FFT depends on correlation magnitude distribution, frequency search range, resolution requirement and the like. The router 50 is used to arrange a route for the data stream so as to direct the data stream to the proper successive component, such as the mixer 52, coherent integration memory 60, magnitude calculation unit 65 or hypothesis selector 80. The router 50 and the selectors 35, 80 can be implemented by hardware or software controlled blocks. The router 50 and selectors 35, 80 are respectively controlled by hardware logic or a processor (not shown) of the receiver for the data paths according to time and channel multiplexing arrangements, for example.

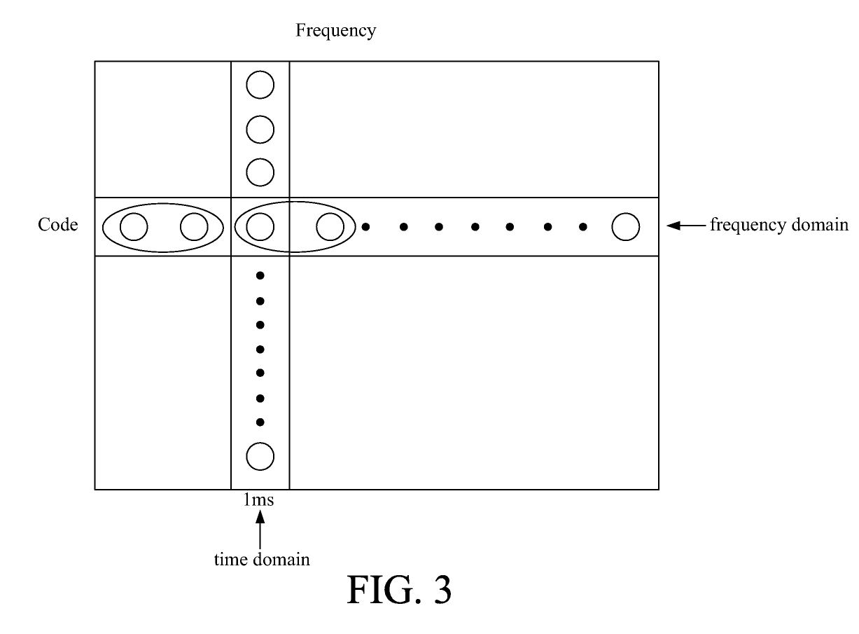

If there are 1023 code phases to be tried for 1 ms, then correlation data for 1023 code phases are calculated for each ms. To promote receiver performance, it is preferred that points with the same code phase at different frequencies are collected to be analyzed. As shown in FIG. 3, the code phase and the frequency construct a two dimensional hypothesis distribution. In frequency domain, 32 or 64 points of the same code phase are collected, for example. That is, those 32 or 64 hypotheses are selected. The post correlation data of the selected hypotheses is sent to be stored in the hypothesis buffer region 306 via the hypothesis selector 80. If the signal strength is weak, or the interested frequency range is narrow but frequency resolution requirement is high, it is preferred to collect the coherent integration result of the correlation data. That is, coherent integration of the hypotheses stored in the coherent integration memory 60 is used. For example, coherent integration results of every two ms for the same code phase are picked from the coherent integration memory 60 to be stored into the hypothesis buffer region 306 via the hypothesis selector 80. The hypothesis selector 80 selects to feed the post correlation data or the coherent integration result of the post correlation data to the hypothesis buffer 306 (step S80).

The data of the selected hypotheses is then sent to the FFT engine 40 through the selector 35 to be processed with FFT operation, which is referred to as “post-correlation FFT” (step S90). The frequency spectrum of the data obtained by the post-correlation FFT is stored into a memory 70. The memory is used as a spectrum memory for storing the spectrum and as an incoherent integration memory. Alternatively, the memory 70 is used only as a spectrum memory. In some circumstances, the memory 70 can store only the post-correlation spectrums, since the correlation peak and correct code phase can be derived from the spectrums. In addition, it is possible to store only the spectrum results of the top N frequency bins in the memory 70 to reduce the memory capacity requirement. For example, as the post-correlation FFT outputs are generated, only the top two or three spectrum results are stored with the frequency bin indices thereof. By doing so, the memory capacity requirement is reduce, while information for handling multi-tone jammer, for example, still remains. The magnitude calculation unit 65 is used to calculate a magnitude from the spectrum (step S100), so that a peak can be found to determine whether signal acquisition is achieved, for example. The magnitude calculation unit 65 calculates the magnitudes for the coherent integration result from the coherent integration memory 60 for incoherent integration and the spectrum obtained by the post-FFT in a TDM manner.

As described above, the FFT engine 40 is shared for pre-correlation FFT/IFFT and the post-correlation FFT. In addition, different channels can share the same FFT engine 40. The sharing scheme can be implemented in a time multiplexing manner (e.g. TDM). The TDM sequence for the pre-correlation FFT, IFFT and post-FFT is adjustable to optimize the performance or as required. If the FFT engine 40 is shared between acquisition mode and tracking mode, the collection trends, especially for the post-correlation FFT, are different. In acquisition mode, it is necessary to search a wide code phase range, but for a specific code phase, the collected points can be less. In tracking mode, the code phase is substantially determined, so there is no need to search a wide code phase range. For the determined small code phase range, more points can be collected to achieve a better performance.

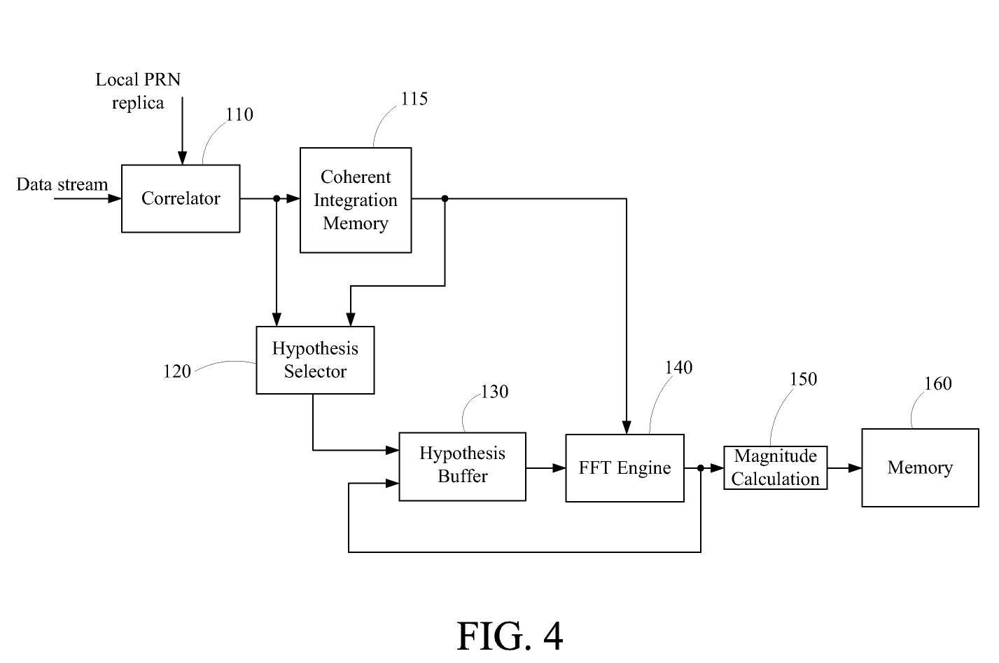

In accordance with the present invention, the post-correlation FFT can also cooperate with time-domain correlation. FIG. 4 is a block diagram schematically and generally showing a rear portion of a GNSS receiver in accordance with a second embodiment of the present invention. In FIG. 4, the components before a correlator 110, such as antenna, RF front end and Doppler wipe off unit connected therewith, are omitted for simplicity and clarity. As with reference to FIG. 2, in the present embodiment, the receiver has the time-domain correlator 110. The correlator 110 executes correlation operations to an input data stream (step S60), which has been down-converted and digitized, with delayed versions of a local PRN code replica for each hypothesis in a TDM manner, as well known in this field. The correlation result of each hypothesis is accumulated in a coherent integration memory 115 for coherent integration (step S70). If the hypothesis is selected (step S75), the correlation result thereof is also passed to a hypothesis buffer 130 as a point via a hypothesis selector 120. As in the first embodiment, the hypothesis selector 120 can also select to pass coherent integration results to the hypothesis buffer 130 if the signal strength is weak or for other considerations (step S80). It is noted that, in all embodiments, the hypotheses may be selected at any proper stage. The step (S75) shown in the flow chart of FIG. 2 is only arranged for example.

The data stored in the hypothesis buffer 130 is sent to an FFT engine 140, which can be implemented by an FFT kernel. The FFT engine 140 executes FFT operation to the data so as to generate post-correlation FFT data (step S90), that is, spectrums of the hypotheses, which can be referred to as post-correlation spectrums. To determine a correlation peak, it is necessary to calculate magnitudes of the spectrums by a magnitude calculation unit 150, which is also shared to calculate magnitudes of the coherent integration results from the coherent integration memory 115 for incoherent integration (step S100). The spectrums obtained from the FFT engine 140 and the calculated magnitudes thereof are stored in a memory 160, which is used as a spectrum memory. The memory 160 can also be used as an incoherent integration memory for accumulating coherent integration results at the same time. Information for signal acquisition and tracking can be derived from the post-correlation spectrum. Therefore, the post-FFT provides the benefits to promote the receiver performance.

In the receiver of the present invention, some components are shared, such as the FFT engine, magnitude calculation unit and the memories. Therefore, the hardware complexity can be reduced.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A correlation system for a Global Navigation Satellite System (GNSS) receiver comprising:
an FFT data buffer for storing a data stream;
an FFT/IFFT engine for executing FFT operation to the data stream from the FFT data buffer to generate a pre-correlation FFT result;
a mixer for correlating the pre-correlation FFT result with a code converted into frequency domain to generate a frequency-domain correlation result;
an inverse-FFT (IFFT) data buffer for storing the frequency-domain correlation result, the FFT/IFFT engine further executing IFFT operation to the frequency-domain correlation result from the IFFT data buffer to generate post correlation data; and
a coherent integration memory for accumulating the post correlation data for coherent integration of the data stream.

2. The correlation system of claim 1, further comprising a hypothesis buffer, the post correlation data being stored in the hypothesis buffer.

3. The correlation system of claim 2, wherein the FFT data buffer, IFFT data buffer and hypothesis buffer are different parts of a data buffer.

4. The correlation system of claim 3, wherein the post correlation data of the selected hypotheses is passed to the FFT engine, and the FFT engine generates a post-correlation FFT result thereof.

5. The correlation system of claim 4, further comprising a magnitude calculation unit for calculating a magnitude for the post-correlation FFT result.

6. The correlation system of claim 5, wherein the magnitude calculation unit also calculates a magnitude for the post correlation data or the coherent integration result of the post correlation data.

7. The correlation system of claim 6, further comprising a spectrum memory for storing the post-correlation FFT result.

8. The correlation system of claim 7, wherein the spectrum memory also accumulates the coherent integration results from the coherent integration memory for incoherent integration of the signal.

9. The correlation system of claim 2, further comprising a first selector for selecting to pass one of the data stream, the frequency-domain correlation result and the post correlation data to be passed to the FFT engine.

10. The correlation system of claim 1, further comprising a hypothesis buffer, coherent integration result of the post correlation data for a hypothesis of the data stream being stored in the hypothesis buffer if the hypothesis is selected.

11. The correlation system of claim 10, wherein the coherent integration results of the selected hypotheses are passed to the FFT engine, and the FFT engine generates a post correlation FFT result thereof.

12. The correlation system of claim 11, further comprising a second selector for selecting to pass the post correlation data or the coherent integration result of the post correlation data to be stored in the hypothesis buffer.

13. The correlation system of claim 1, further comprising a router for designating a path for an output from the FFT engine.

14. The correlation system of claim 1, wherein the FFT engine comprises a plurality of sub-FFT units.

15. The correlation system of claim 1, wherein the FFT engine executes FFT operation and IFFT operation in a time division multiplexing (TDM) manner.

16. The correlation system of claim 1, wherein the FFT engines executes operations for a plurality of channels in a TDM manner.

17. A correlation system for a Global Navigation Satellite System (GNSS) receiver comprising:
a correlator for executing correlation operation to a data stream to generate post correlation data;
a coherent integration memory for accumulating the post correlation data for coherent integration of the post correlation data; and
an FFT engine executing FFT operation to the post correlation data or the coherent integration result of the post correlation data for selected hypotheses of the data stream to generate a post-correlation FFT result thereof.

18. The correlation system of claim 17, further comprising a hypothesis selector for selecting to pass the post correlation data or the coherent integration result of the post correlation data to the FFT engine.

19. The correlation system of claim 17, further comprising a hypothesis buffer for storing the post correlation data or the coherent integration result of the post correlation data of the selected hypotheses.

20. The correlation system of claim 17, further comprising a magnitude calculation unit for calculating a magnitude for the post-correlation FFT result.

21. The correlation system of claim 20, wherein the magnitude calculation unit also calculates a magnitude for the post correlation data or the coherent integration result of the post correlation data.

22. The correlation system of claim 17, further comprising a spectrum memory for storing the post-correlation FFT result.

23. The correlation system of claim 22, wherein the spectrum memory also accumulates the coherent integration results from the coherent integration memory for incoherent integration of the signal.

24. The correlation system of claim 17, wherein the FFT engine comprises a plurality of sub-FFT units.

25. The correlation system of claim 17, wherein the FFT engines executes operations for a plurality of channels in a TDM manner.

26. A correlation method for Global Navigation Satellite System (GNSS) receiver,
said method comprising:
executing correlation operation to a data stream to generate post correlation data;
accumulating the post correlation data to obtain a coherent integration result;
selecting the post correlation data or the coherent integration result thereof; and
conducting FFT operation to the selected post correlation or the coherent integration result to generate a post correlation FFT result.

27. The correlation method of claim 26, wherein the correlation operation is executed in time domain.

28. The correlation method of claim 26, wherein the correlation operation comprises:
conducting FFT operation to the data stream to generate frequency domain correlation data; and
conducting IFFT operation to the frequency domain correlation data to generate post correlation data.

29. The correlation method of claim 26, further comprising calculating a magnitude for the post correlation FFT result.

30. The correlation method of claim 26 further comprising selecting hypotheses of the data stream, and collecting post correlation data of the selected hypotheses to be conducted with the FFT operation to generate post correlation FFT result thereof.
